(19) United States
(12) Patent Application Publication
(10) Pub. No.: US 2013/0329381 A1
(43) Pub. Date: Dec. 12, 2013

(54) ELECTROMAGNETIC SHIELDING CASE AND ELECTRONIC DEVICE HAVING THE SAME

(71) Applicants: SZU-HAO HUANG, NEW TAIPEI CITY (TW); SHIH-PO LO, NEW TAIPEI CITY (TW)

(72) Inventors: SZU-HAO HUANG, NEW TAIPEI CITY (TW); SHIH-PO LO, NEW TAIPEI CITY (TW)

(73) Assignee: ASKEY COMPUTER CORP.

(21) Appl. No.: 13/567,492

(22) Filed: Aug. 6, 2012

(30) Foreign Application Priority Data
Jun. 7, 2012 (TW) 101120492

(51) Int. Cl. H05K 9/00; H05K 7/00

(52) U.S. Cl. 361/748

(57) ABSTRACT

An electromagnetic shielding case and an electronic device having the same are introduced. The electronic device includes a PCB, which has at least one electronic component mounted thereon and is provided around the electronic component with multiple positioning holes. The electromagnetic shielding case includes a casing body internally defining a shielding space and multiple fixing pins formed on lower edges of the casing body corresponding to the positioning holes on the PCB. Each fixing pin includes a neck portion and an end portion with an angle included therebetween. After the fixing pins are correspondingly extended through the positioning holes, the end portions can be deflected by an angle to thereby hold the casing body to the PCB with the electronic component located in the shielding space and shielded against EMI. With these arrangements, the electromagnetic shielding case can be quickly mounted to and dismounted from the PCB.

### CROSS-REFERENCE TO RELATED APPLICATION

This non-provisional application claims priority under 35 U.S.C. §119(a) on Patent Application No(s). 101120492 filed in Taiwan, R.O.C. on Jun. 7, 2012, the entire contents of which are hereby incorporated by reference.

### FIELD OF TECHNOLOGY

The present invention relates to an electromagnetic shielding case, and more particularly to an electronic device having an electromagnetic shielding case connected to a printed circuit board thereof for shielding at least one electronic component on the printed circuit board against electromagnetic interference.

### BACKGROUND

To protect an electronic device, such as a smartphone, a tablet computer or a portable computer, against lowered operational performance due to electromagnetic interference (EMI), a conventional solution is to cover a metal shielding case 6 on an area of a printed circuit board (PCB) 2 of the electronic device by means of surface-mount technology (SMT), so that an electronic component 4 mounted on the PCB 2 is enclosed in the metal shielding case 6 and shielded against EMI, as shown in FIG. 1. To do so, first apply an amount of solder paste to a location on the PCB 2, at where the metal shielding case 6 is to be connected to the PCB 2. Then, align the metal shielding case 6 with the location having the solder paste applied thereto and cover the metal shielding case 6 on the PCB 2. Finally, soften the applied solder paste with a reflow oven to thereby solder the metal shielding case 6 to the PCB 2.

When it is necessary to dismount the metal shielding case 6 for the purpose of examining or replacing the electronic component 4 on the PCB 2, rework is required to desolder the metal shielding case 6 from the PCB 2 before the metal shielding case 6 can be removed to expose the electronic component 4. The above procedures for mounting and dismounting the metal shielding case 6 to and from the PCB 2 are troublesome and consume a lot of time and labor.

It is therefore tried by the inventor to develop an improved electromagnetic shielding case and an electronic device having the same, so that the electromagnetic shielding case not only effectively shields electronic components on the PCB of the electronic device against EMI, but also can be quickly mounted to and dismounted from the PCB as necessary.

### SUMMARY

A primary object of the present invention is to provide an electromagnetic shielding case that can be quickly mounted to a printed circuit board (PCB) of an electronic device for shielding electronic components on the PCB against electromagnetic interference, and can be quickly dismounted from the PCB for replacement or examination of the electronic components.

Another object of the present invention is provide an electronic device that internally has an electromagnetic shielding case, which can be quickly mounted to a printed circuit board (PCB) of the electronic device for shielding electronic components on the PCB against electromagnetic interference, and can also be quickly dismounted from the PCB for replacement or examination of the electronic components.

To achieve the above and other objects, the electronic device according to the present invention internally includes a printed circuit board (PCB) and an electromagnetic shielding case. The PCB has at least one electronic component mounted on one face thereof and is provided around the electronic component with a plurality of positioning holes. The electromagnetic shielding case includes a casing body internally defining a shielding space, and a plurality of fixing pins formed on lower edges of the casing body corresponding to the positioning holes on the PCB. Each of the fixing pin includes a neck portion connected to the lower edge of the casing body and an end portion extended from the neck portion; and the fixing pin is so formed that an angle is included between the neck portion and the end portion. When the fixing pins have been correspondingly extended through the positioning holes from the face of the PCB with the electronic component mounted thereon, the end portions are respectively projected from a reverse face of the PCB and can be deflected by an angle to thereby become pressed against the reverse face of the PCB, so that the casing body is firmly held to the PCB with the electronic component located in the shielding space and shielded against EMI.

To achieve the above and other objects, the electromagnetic shielding case according to the present invention is configured for detachably mounting to a PCB in an electronic device. The PCB has at least one electronic component mounted on one face thereof and is provided around the electronic component with a plurality of positioning holes. The electromagnetic shielding case includes a casing body internally defining a shielding space, and a plurality of fixing pins formed on lower edges of the casing body corresponding to the positioning holes on the PCB. Each of the fixing pin includes a neck portion connected to the lower edge of the casing body and an end portion extended from the neck portion; and the fixing pin is so formed that an angle is included between the neck portion and the end portion. When the fixing pins have been correspondingly extended through the positioning holes from the face of the PCB with the electronic component mounted thereon, the end portions are respectively projected from a reverse face of the PCB and can be deflected by an angle to thereby become pressed against the reverse face of the PCB, so that the casing body is firmly held to the PCB with the electronic component located in the shielding space and shielded against EMI.

Compared to the prior art metal shielding case, the electromagnetic shielding case of the present invention is characterized by including a casing body that can be mounted to or dismounted from a printed circuit board (PCB) in an electronic device via a plurality of fixing pins formed on lower edges of the casing body corresponding to a plurality of positioning holes provided around at least one electronic component mounted on the PCB. By extending the fixing pins through the positioning holes and deflecting end portions of the fixing pins by an angle, the casing body is firmly held to the PCB to enclose the electronic component and shield it against EMI. On the other hand, by deflecting the end portions of the fixing pins reversely, the fixing pins can be easily disengaged from the positioning holes and the casing body can be quickly dismounted from the PCB to enable necessary replacement or examination of the electronic component.

With the electromagnetic shielding case that can be quickly mounted to or dismounted from the PCB, the electronic components on the PCB can be effectively shielded against EMI and can be easily replaced or examined when necessary.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 schematically shows the mounting of a conventional metal shielding case to a printed circuit board;

FIG. 2 is a top perspective view of an electromagnetic shielding case according to an embodiment of the present invention;

FIG. 3 is a bottom perspective view of the electromagnetic shielding case of FIG. 2;

FIG. 4 is an exploded perspective view schematically showing an electronic device having electromagnetic shielding case according to an embodiment of the present invention;

FIGS. 5 and 6 illustrate the mounting of the electromagnetic shielding case to a printed circuit board of the electronic device shown in FIG. 4; and

FIG. 7 is a flowchart showing the steps included in a method of mounting the electromagnetic shielding case of the present invention to a printed circuit board.

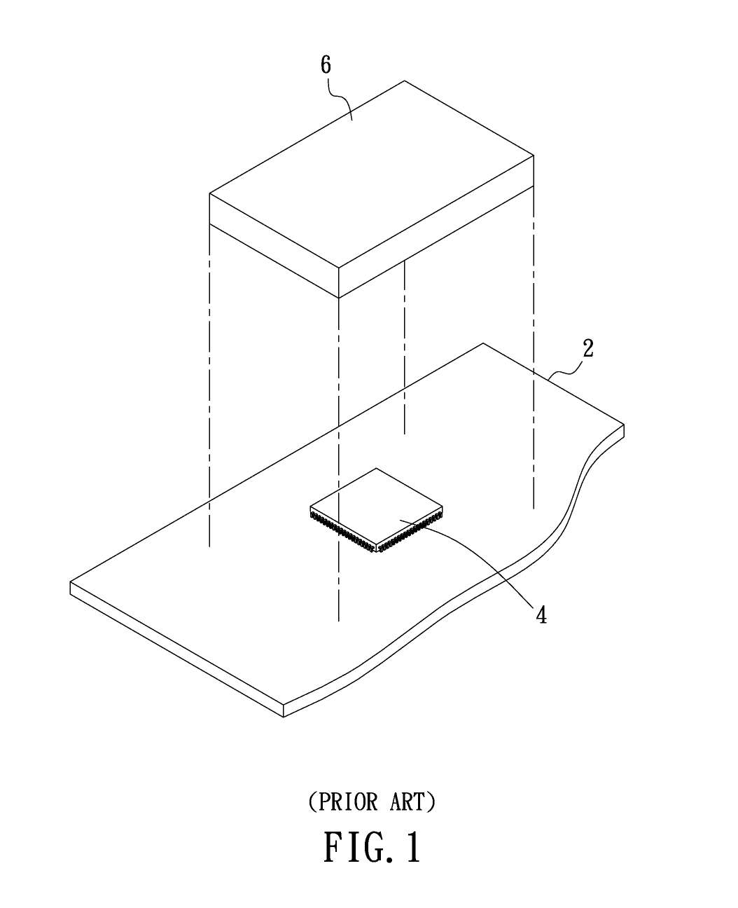

### DETAILED DESCRIPTION

The present invention will now be described with a preferred embodiment thereof and with reference to the accompanying drawings.

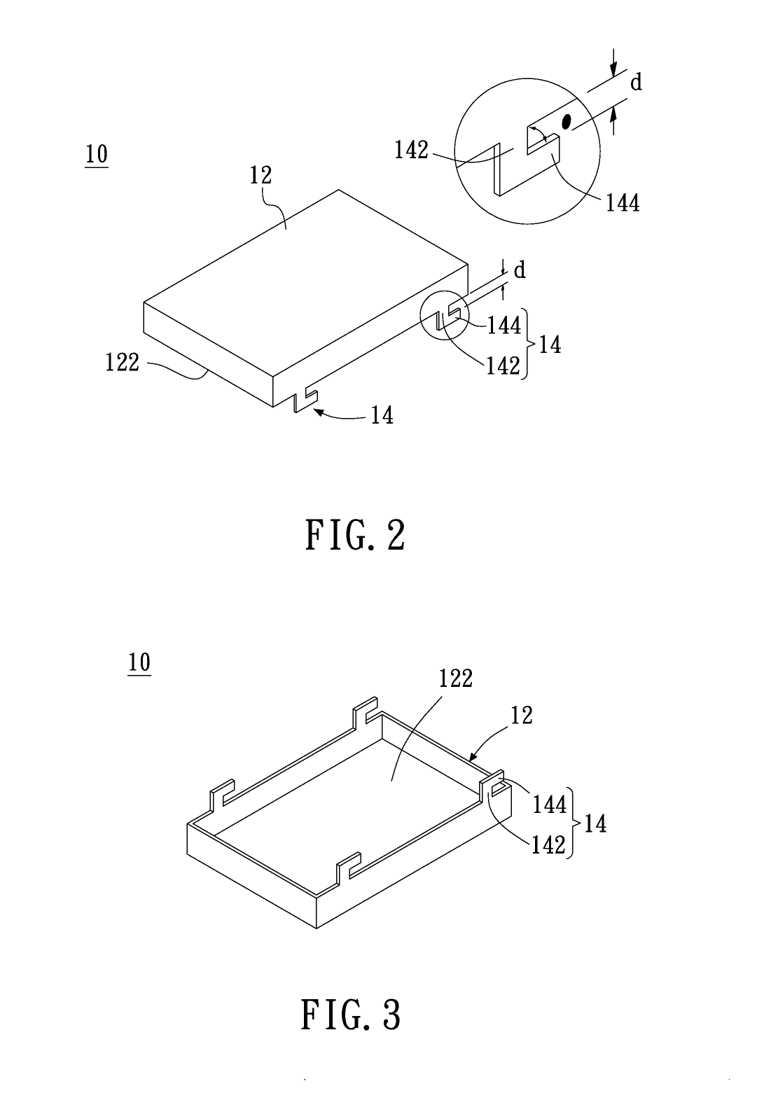

Please refer to FIGS. 2 and 3 that are top and bottom perspective views, respectively, of an electromagnetic shielding case 10 according to an embodiment of the present invention. As shown, the electromagnetic shielding case 10 is configured for mounting to a printed circuit board (not shown in FIGS. 2 and 3). The printed circuit board (PCB) has at least one electronic component mounted on one face thereof and is provided around the electronic component with a plurality of positioning holes. Wherein, the electromagnetic shielding case 10 includes a casing body 12 and a plurality of fixing pins 14.

The casing body 12 internally defines a shielding space 122 for accommodating the at least one electronic component therein. The casing body 12 may be of any shape and is usually configured corresponding to an area on the PCB that requires electromagnetic shielding. In the illustrated embodiment, the casing body 12 is shown as a rectangular casing.

The fixing pins 14 are formed on lower edges of the casing body 12 corresponding to the positioning holes on the printed circuit board. Each of the fixing pin 14 includes a neck portion 142 connected to the lower edge of the casing body 12 and an end portion 144 extended from the neck portion 142. The fixing pin 14 is so formed that an angle θ is included between the neck portion 142 and the end portion 144, and a space d is formed between the end portion 144 and the lower edge of the casing body 12. After the fixing pins 14, including the end portions 144, are correspondingly extended through the positioning holes, the end portions 144 can respectively be deflected by an angle to thereby hold the casing body 12 to the PCB for covering the electronic component. Wherein, the included angle θ is smaller than or equal to 90°, and the space d is a smallest possible distance from the end portion 144 to the casing body 12 and can be smaller than, larger than, or equal to a thickness of the PCB. With these arrangements, the fixing pins 14 can be fixedly retained to a reverse face of the PCB via the deflected end portions 144. Further, the fixing pins 14 not only hold but also clamp the electromagnetic shielding case 10 to the PCB, so as to provide required electromagnetic shielding effect around the electronic component and protect the electronic component against electromagnetic interference (EMI).

In the illustrated embodiment, the included angle θ is shown as 90°, so that the neck portion 142 and the end portion 144 together form an L-shaped fixing pin 14. In other embodiments not shown herein, the neck portion 142 and the end portion 144 can together form a T-shaped or other suitably-shaped fixing pin 14.

Further, the number of the fixing pins 14 is not necessarily limited to four as that showing in FIG. 3. For example, the electromagnetic shielding case 10 can have only three fixing pins 14. Any specific number of the fixing pins 14 shall fall in the scope of the present invention so long as the fixing pins 14 can firmly and stably hold the casing body 12 to the PCB.

The casing body 12 and the fixing pins 14 can be integrally formed with one another or be separately manufactured and then assembled together. In the illustrated embodiment, the casing body 12 and the fixing pins 14 are shown as being integrally formed with one another.

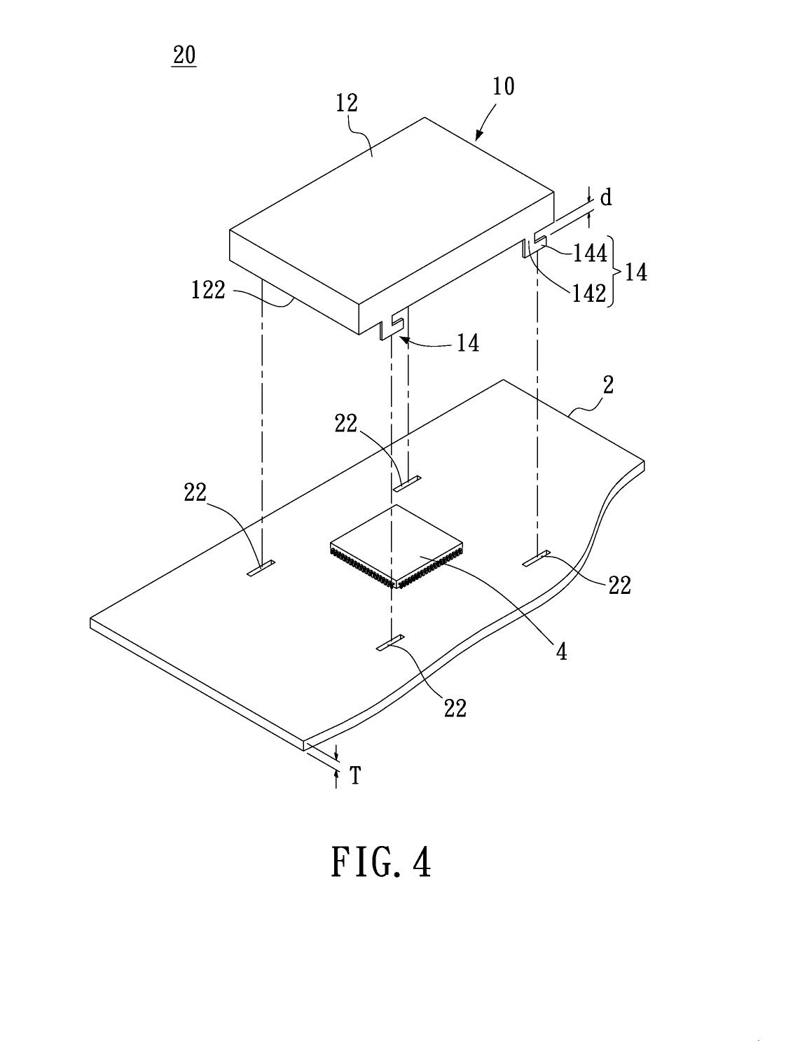

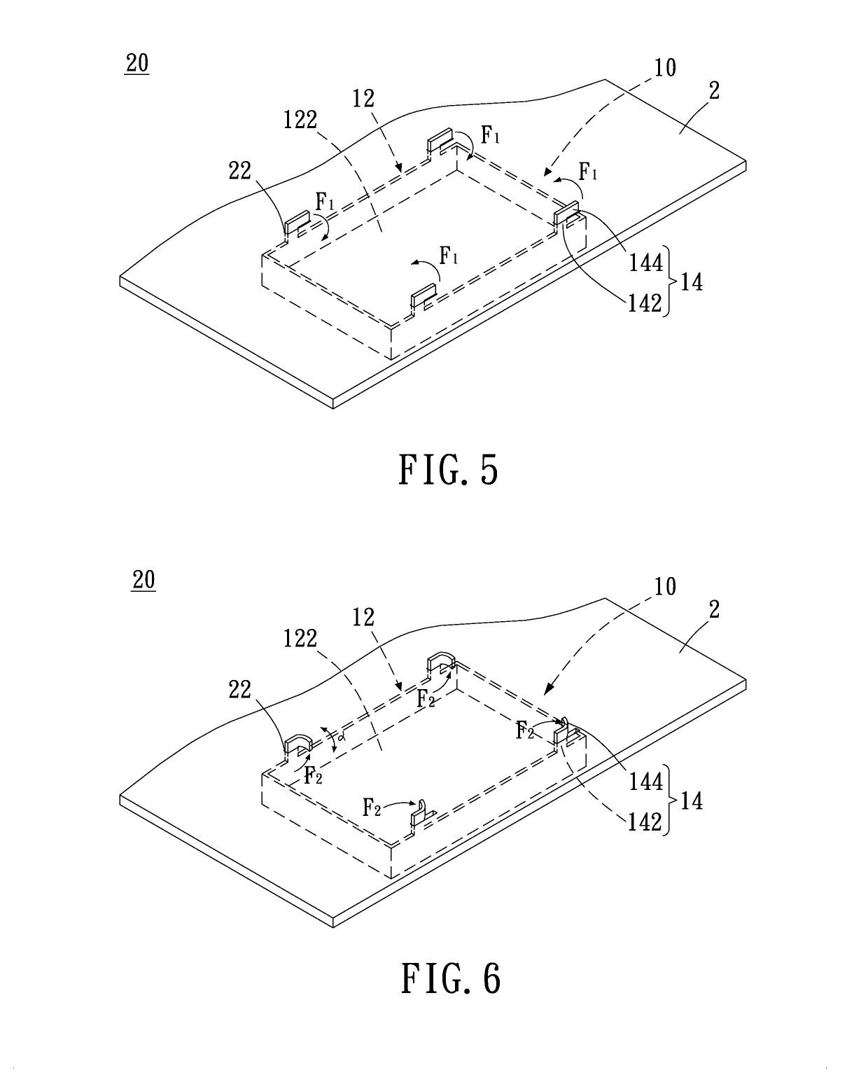

Please refer to FIG. 4 that is an exploded perspective view schematically showing an electronic device having electromagnetic shielding case according to an embodiment of the present invention, and to FIGS. 5 and 6 that respectively show the mounting and dismounting of an electromagnetic shielding case to and from a PCB of the electronic device. As can be seen in FIG. 4, the electronic device having electromagnetic shielding case according to the present invention is generally denoted by reference numeral 20, and includes a PCB 2 and an electromagnetic shielding case 10. The PCB 2 has at least one electronic component 4 mounted on one face thereof and is provided around the electronic component 4 with a plurality of positioning holes 22. The electromagnetic shielding case 10 is configured to shield the electronic component 4 on the PCB 2 against EMI. The electromagnetic shielding case 10 includes a casing body 12 and a plurality of fixing pins 14 for correspondingly extending through the positioning holes 22. That is, the neck portion 142 and the end portion 144 of each of the fixing pins 14 are extended through one corresponding positioning hole 22 to thereby hold the electromagnetic shielding case 10 to the PCB 2. The end portions 144 of the fixing pins 14 extended through the positioning holes 22 and located behind the PCB 2 are then respectively deflected by an angle α, as indicated in FIG. 6, so that the electromagnetic shielding case 10 is firmly mounted to the PCB 2 via the deflected end portions 144 of the fixing pins 14 to cover the electronic component 4 therein.

In each of the fixing pins 14, the neck portion 142 and the end portion 144 together include an angle θ between them, and there is a space d formed between each end portion 144 and the lower edge of the casing body 12. In the illustrated embodiment, the space d is shown as being equal to a thickness T of the PCB 2. Therefore, when the electromagnetic shielding case 10 has been mounted on the PCB 2, the lower edges of the casing body 2 are completely pressed against the face of the PCB 2 having the electronic component 4 mounted thereon, and the electronic component 4 is completely enclosed in the casing body 12 and shielded against EMI.

Please also refer to FIG. 5, which is a bottom view of FIG. 4 but with the electromagnetic shielding case 10 already connected to the PCB 2. In FIG. 5, the neck portions 142 of the fixing pins 14 are correspondingly located in the positioning holes 22 with the end portions 144 projected from a reverse face of the PCB 2 opposite to the electronic component 4.

Thereafter, a tool (not shown) is used to apply a rotational force to each of the end portions 144 projected from the reverse face of the PCB 2 in a direction such as that indicated by the arrow F1, so that the end portion 144 is bent and deformed in the direction F1. As a result, a free end of each of the end portions 144 is deflected from the corresponding positioning hole 22 by a deflection angle α while tightly pressing against the reverse face of the PCB 2, as shown in FIG. 6. In this manner, the casing body 12 is now firmly and stably retained to the PCB 2.

Alternatively, after the fixing pins 14 have been correspondingly extended through the positioning holes 22, the whole electromagnetic shielding case 10 is translated along a longitudinal direction of the positioning holes 22, so that the fixing pins 14 are directly hooked and clamped to the PCB 2 through engagement the PCB 2 with the space d.

It is possible the neck portions 142 of the fixing pins 14 are also twisted by a certain degree when the end portions 144 are deflected under the applied rotational force. Therefore, it is understood the degree by which the neck portions 142 are twisted or the angle α by which the end portions 144 are deflected is not necessarily limited to that shown in the drawings. Any manner that can bring the end portions 144 to be stably retained to the reverse face of the PCB 2 shall fall in the scope of the present invention.

In another feasible embodiment not particularly shown in the drawings, the included angle θ can be smaller than 90°. In this case, the space d between the end portions 144 and the lower edges of the casing body 12 is smaller than the thickness T of the PCB 2. Therefore, when the fixing pins 14 are rotated by a force applied thereto in a direction parallel to the PCB 2, the end portions 144 would be brought not only to hook to but also tightly press against the reverse face of the PCB 2 in a slightly bent and deformed manner. That is, with the end portions 144 in a deflected state, the fixing pins 14 can be firmly retained to the PCB 2. More specifically speaking, the fixing pins 14 with an included angle θ smaller than 90° can provide a retaining force larger than that can be provided by the fixing pins 14 with an included angle θ equal to 90°, when the end portions 144 thereof are deflected in the above-described manner, and can therefore more firmly and tightly hold the casing body 12 to the PCB 2.

In still another feasible embodiment not particularly shown herein, the space d between the end portions 144 and the lower edges of the casing body 12 can be larger than the thickness T of the PCB 2. In this case, the end portions 144 can be bent by a force applied thereto in a direction toward the PCB 2, so that the end portions 144 are deflected while pressing against the reverse face of the PCB 2.

Please refer to FIG. 6 again. When it is necessary to dismount the electromagnetic shielding case 10 from the PCB 2 in order to replace or examine the electronic component 4 covered by the casing body 12, the same tool may be used to deflect each of the end portions 144 in a reverse direction F2 for the end portions 144 to return to their original position as shown in FIG. 5. At this point, the end portions 144 no longer hook to or clamp to the PCB 2 and the whole electromagnetic shielding case 10 can be easily removed from the PCB 2 to expose the electronic component 4 for further replacement or examination thereof. When the electronic component 4 has been replaced or examined, simply reverse the above steps to mount the electromagnetic shielding case 10 to the PCB 2 again.

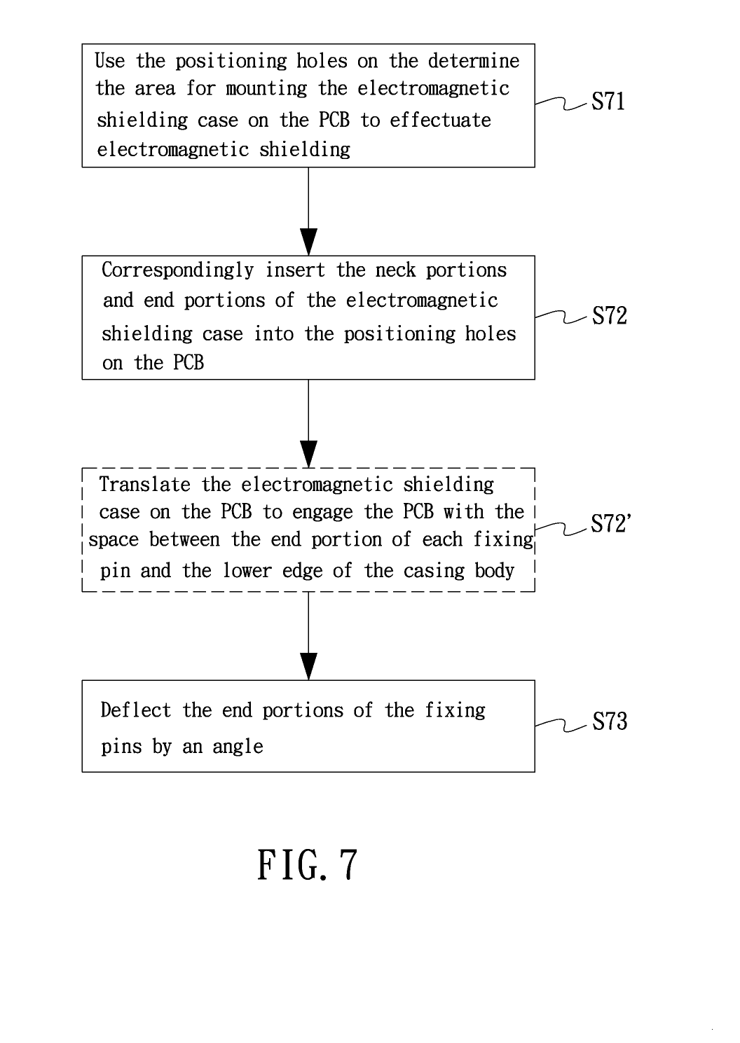

FIG. 7 is a flowchart showing the steps included in a method of mounting an electromagnetic shielding case according to an embodiment of the present invention. With the mounting method illustrated in FIG. 7, an electromagnetic shielding case can be mounted to a PCB for shielding an electronic component on the PCB against EMI. The PCB has at least one electronic component mounted thereon and is provided around the electronic component with a plurality of positioning holes. The electromagnetic shielding case is configured for connecting to the PCB and includes a casing body and a plurality of fixing pins; and the fixing pins respectively include a neck portion connected to a lower edge of the casing body and an end portion extended from the neck portion with an angle included between the neck portion and the end portion.

In a first step S71 of the electromagnetic shielding case mounting method, an area on the PCB for mounting the electromagnetic shielding case to effectuate the electromagnetic shielding purpose is determined according to the locations of the positioning holes.

In a second step S72, the neck portions and the end portions of the electromagnetic shielding case are correspondingly inserted into the positioning holes, so that the casing body is attached to one face of the PCB and covers the electronic component therein while the end portions of the fixing pins are projected from a reverse face of the PCB.

And, in a third step S73, a force is applied to the end portions to deflect them by an angle, so that the electromagnetic shielding case is firmly held to the PCB via the deflected end portions that are pressed against the reverse face of the PCB. In some other embodiments, the force can be applied to the end portions in a direction parallel to the PCB or in a direction toward the PCB.

According to another embodiment of the mounting method of the present invention, a step S72′ is further performed after the second step S72. In the step S72′, the electromagnetic shielding case is translated on the PCB, so that the space between each end portion and the lower edge of the casing body becomes engaged with the PCB while the end portions are pressed against the reverse face of the PCB to thereby firmly hold the electromagnetic shielding case to the PCB.

In brief, the electromagnetic shielding case according to the present invention has a casing body, which can be connected to a PCB through engagement of a plurality of fixing pins provided on lower edges of the casing body with a plurality of positioning holes formed on the PCB, so as to shield the electronic component on the PCB against EMI. Compared to the prior art metal shielding case, the electromagnetic shielding case of the present invention can be more easily mounted to or dismounted from the PCB in upgraded efficiency. Therefore, the electronic device having the electromagnetic shielding case of the present invention is more advantageous for use.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An electronic device having electromagnetic shielding case, comprising:
a printed circuit board (PCB) having at least one electronic component mounted on one face thereof and being provided around the electronic component with a plurality of positioning holes; and
an electromagnetic shielding case including a casing body and a plurality of fixing pins; the casing body internally defining a shielding space, and the fixing pins being formed on lower edges of the casing body corresponding to the positioning holes on the PCB; each of the fixing pin including a neck portion connected to the lower edge of the casing body and an end portion extended from the neck portion; and the fixing pin being so formed that an angle is included between the neck portion and the end portion;
wherein when the fixing pins have been correspondingly extended through the positioning holes from the face of the PCB with the electronic component mounted thereon, the end portions are respectively projected from a reverse face of the PCB and can be deflected by an angle to thereby become pressed against the reverse face of the PCB, so that the casing body is firmly held to the PCB with the electronic component located in the shielding space and shielded against EMI.

2. The electronic device having electromagnetic shielding case as claimed in claim 1, wherein the included angle between the neck portion and the end portion is smaller than or equal to 90°.

3. The electronic device having electromagnetic shielding case as claimed in claim 1, wherein the casing body and the fixing pins are integrally formed with one another.

4. The electronic device having electromagnetic shielding case as claimed in claim 1, wherein the casing body and the fixing pins are separately manufactured and then assembled together to form the electromagnetic shielding case.

5. The electronic device having electromagnetic shielding case as claimed in claim 1, wherein each of the fixing pins formed from the neck portion and the end portion has a shape selected from the group consisting of an L shape and a T shape.

6. The electronic device having electromagnetic shielding case as claimed in claim 1, wherein each of the end portions is deflected by applying a force thereto in a direction parallel to the PCB.

7. An electromagnetic shielding case for mounting to a printed circuit board (PCB), the PCB having at least one electronic component mounted on one face thereof and being provided around the electronic component with a plurality of positioning holes; comprising:
a casing body internally defining a shielding space for accommodating the electronic component therein; and
a plurality of fixing pins being formed on lower edges of the casing body corresponding to the positioning holes on the PCB; each of the fixing pin including a neck portion connected to the lower edge of the casing body and an end portion extended from the neck portion, such that an angle is included between the neck portion and the end portion;
wherein when the fixing pins have been correspondingly extended through the positioning holes from the face of the PCB with the electronic component mounted thereon, the end portions are respectively projected from a reverse face of the PCB and can be deflected by an angle to thereby become pressed against the reverse face of the PCB, so that the casing body is firmly held to the PCB with the electronic component located in the shielding space and shielded against EMI.

8. The electromagnetic shielding case as claimed in claim 7, wherein the included angle between the neck portion and the end portion is smaller than or equal to 90°.

9. The electromagnetic shielding case as claimed in claim 7, wherein the casing body and the fixing pins are integrally formed with one another.

10. The electromagnetic shielding case as claimed in claim 7, wherein the casing body and the fixing pins are separately manufactured and then assembled together to form the electromagnetic shielding case.

11. The electromagnetic shielding case as claimed in claim 7, wherein each of the fixing pins formed from the neck portion and the end portion has a shape selected from the group consisting of an L shape and a T shape.

12. The electromagnetic shielding case as claimed in claim 7, wherein each of the end portions is deflected by applying a force thereto in a direction parallel to the PCB.
